(19) United States
(12) Patent Application Publication
(10) Pub. No.: US 2005/0112876 A1
(43) Pub. Date: May 26, 2005

(54) Method to form a robust TiCI4 based CVD TiN film

(76) Inventors: Chih-Ta Wu, Hsin-chu City (TW); Kuo Yin Lin, Taichung (TW); Min-Hsiung Chiang, Banciao city (TW)

Correspondence Address: George O. Saile & Associates, 28 Davis Avenue, Poughkeepsie, NY, 12603, US

(21) Appl. No.: 10/723,237

(22) Filed: Nov. 26, 2003

(51) Int. Cl. H01L 21/20

(52) U.S. Cl. 438/685; 438/584; 438/658

(57) ABSTRACT

A method is described for a plasma treatment of a TiCl₄ based CVD deposited TiN layer that reduces stress, lowers resistivity, and improves film stability. Resistivity is stable in an air ambient for up to 48 hours after the plasma treatment. A TiN layer is treated with a N-containing plasma that includes N₂, NH₃, or N₂H₄ at a temperature between 500° C. and 700° C. Optionally, H₂ may be added to N₂ in the plasma step which removes chloride impurities and densifies the TiN layer. The TiN layer may serve as a barrier layer, an ARC layer, or as a bottom electrode in a MIM capacitor. An improved resistance of the treated TiN layer to oxidation during formation of an oxide based insulator layer and a lower leakage current in the MIM capacitor is also achieved.

### FIELD OF THE INVENTION

The invention relates to a method of fabricating an integrated circuit in a semiconductor device. More particularly, the present invention relates to a method of treating a TiN layer deposited by a chemical vapor deposition (CVD) method to provide a transformed film with lower resistivity and less stress and with improved stability.

### BACKGROUND OF THE INVENTION

CVD and plasma enhanced CVD (PECVD) methods are frequently used in the semiconductor industry for depositing a uniform layer such as an etch stop layer, dielectric layer, or barrier layer on a substrate. A CVD or PECVD method provides better step coverage than a physical vapor deposition (PVD) method and is especially useful when a conformal film must be deposited in an opening such as a contact hole having a small width and a high aspect ratio of about 3 or more. Typically, a CVD process is performed by flowing two or more reactant gases into a heated reaction chamber at a reduced pressure to deposit a film that may vary from a few Angstroms to several thousand Angstroms in thickness. In a PECVD technique, a plasma is generated in the reaction chamber to increase the deposition rate. In one example, TiCl₄ and NH₃ react to form a TiN layer in addition to the gaseous by-products HCl and N₂. Likewise, other metal nitrides such as TaN or WN may be produced by reacting an appropriate metal source gas and a nitrogen source gas. Silicon and oxygen containing layers such as a SiCOH dielectric layer may be generated by a CVD or PECVD approach that employs an appropriate silicon source gas and an oxidizing gas.

A CVD method is not without some drawbacks, however. Contaminants such as chloride ions may become trapped within a TiCl₄ based TiN film and degrade device performance if not removed in a subsequent step. When TiCl₄ is used to form a TiN layer, chloride contamination is a concern particularly at deposition temperatures below 500° C. One method that is employed to overcome this problem is an in-situ soaking or gas thermal treatment with NH₃. The gaseous NH₃ reacts with a chloride ion in the deposited film to form gaseous NH₄Cl which is removed through an exit port in the process chamber. However, this technique is not effective in reducing the chloride concentration to an acceptable level for advanced technologies.

Another concern is the porosity of a CVD deposited layer. For example, in a SiCOH film the porous nature of the layer lowers the dielectric constant but makes the SiCOH film susceptible to water absorption. Thus, a post-deposition treatment may be required to densify the SiCOH layer and improve its stability. Similarly, a post-deposition treatment of a CVD deposited TiN layer may be required in order for densification to occur. Preferably, a process that improves TiN film properties involves only one step to minimize cost and enable high throughput in the manufacturing line.

A TiN layer is used as an anti-reflective coating (ARC) in the fabrication of metal lines in which a photoresist is coated and patterned over the TiN layer and then serves as an etch mask while the pattern is transferred through TiN and an underlying metal layer. A TiN layer is also an effective barrier layer between a metal layer and a dielectric layer such as in a damascene sequence in which a TiN film is deposited within an opening in a dielectric layer and then a metal layer is deposited on the TiN layer to form an interconnect. Here the TiN layer functions as a nucleation site for the metal deposition that fills the opening and prevents metal ions from migrating into the adjacent dielectric layer.

A third application for a TiN layer is in a MIM capacitor where the TiN serves as a bottom electrode. Besides a low resistivity, an additional requirement in this example is that the TiN layer must be resistant to oxidation since a subsequent process step usually involves the deposition of an oxygen containing insulator layer which exposes the TiN to oxygen. During the deposition of the insulator layer, a titanium oxide layer is likely to form on an untreated TiN layer which will cause a higher leakage current in the final device. Furthermore, a lower stress in the TiN layer is desirable in order to reduce a tendency to crack. Therefore, a post CVD treatment is needed that will reduce TiN resistivity and stress and improve film stability including resistance to oxidation.

A method for removing oxygen from the surface of an oxidized metal layer prior to depositing a subsequent metal layer is disclosed in U.S. Pat. No. 6,297,147. A TiN barrier is deposited by a CVD or PVD method and is oxidized by annealing or exposure to air to improve barrier properties. The titanium oxide surface layer is then removed by a plasma treatment involving N₂ or H₂ or mixtures thereof.

In U.S. Pat. No. 5,970,378, a TiN layer with low impurities and low resistivity is formed by a process that includes a CVD step with a non-halogen source material. Next, a first anneal is performed with a N₂ and H₂ plasma at about 300° C. to 500° C. followed by a second anneal with a N₂ plasma in the same temperature range. Two steps are needed to achieve improved performance in the TiN layer.

A process is described in related prior art U.S. Pat. Nos. 6,207,557 and 6,291,342 for forming a multilayer TiN film comprised of at least two TiN layers on a TiN underlayer. Each of the TiN layers is deposited with TiCl₄ and NH₃ source gases and is annealed with a thermal treatment that uses NH₃ at 530° C. to 680° C. Multiple steps are required to produce a TiN film that is low in chloride impurities.

In U.S. Pat. No. 6,140,243, a TiN glue layer is formed in a contact hole in three steps. The first and third steps employ a PVD process while the second step involves a CVD method. Each of the steps deposits a 20 to 100 Angstrom thick TiN layer. Optionally, grain boundary stuffing occurs on the first and second TiN layers in order to form a titanium oxide layer that blocks gas diffusion pathways.

### SUMMARY OF INVENTION

One objective of the present invention is to provide a method for lowering the resistivity and stress in a TiN layer deposited by a TiCl₄ based CVD method.

A further objective of the present invention is to improve film stability and in particular to provide a more stable film resistivity after a method is performed according to the first objective.

A still further objective of the present invention is to provide a method that improves oxidation resistance in a TiN layer deposited by a TiCl₄ based CVD method and which serves as a bottom electrode in a MIM capacitor.

These objectives are achieved in a first embodiment by providing a substrate with a silicide region that is formed on a gate electrode or on an active area in a transistor structure. An etch stop layer and a dielectric layer are sequentially formed on the transistor and on the silicide regions. A contact hole is formed above a silicide region and extends through the dielectric layer and etch stop layer. Next, a TiN layer that is preferably conformal to the sidewalls and bottom of the contact hole is deposited on the dielectric layer by a CVD method that employs TiCl₄ as a titanium source gas. A key feature is that the TiN layer is subsequently treated with a plasma that includes N₂ or a nitrogen containing gas such as NH₃ or N₂H₄. Optionally, the plasma treatment may involve N₂ in combination with H₂. The plasma treatment is preferably performed “ex-situ” which means in a different chamber than used for the CVD step. The substrate is not exposed to air during the move to another chamber so that titanium oxide layer is not formed on the surface of the TiN layer. A process chamber temperature of at least 500° C. is also used to assist in the removal of impurities from the TiN layer. A conventional sequence is then followed in which a metal layer is deposited on the TiN layer to fill the contact hole and a planarization process is used to make the TiN layer and metal layer coplanar with the top of the dielectric layer.

In a second embodiment, a TiN layer which serves as the bottom electrode in a MIM capacitor is processed according to a method of the present invention. A dielectric layer is deposited on a substrate and a contact hole is formed in the dielectric layer. A TiN layer that is preferably conformal to the sidewalls and bottom of the contact hole is deposited on the dielectric layer by a CVD method that employs TiCl₄ as a titanium source gas. In the following step, a key feature is that the TiN layer is treated with a plasma that includes N₂ or a nitrogen containing gas such as NH₃ or N₂H₄. Optionally, the plasma treatment may involve N₂ in combination with H₂. The plasma treatment is preferably performed “ex-situ” and a process chamber temperature of at least 500° C. is used to assist in the removal of impurities from the TiN layer. The MIM capacitor is then completed by a conventional sequence. For example, the TiN layer may be etched back in the contact hole to a certain depth. An insulator layer is formed on the dielectric layer and within the contact hole and covers the TiN bottom electrode. Finally, a top electrode comprised of a metal layer is formed on the insulator layer.

### BRIEF DESCRIPTION OF THE DRAWINGS

FIG. 1 is a cross-sectional view of a transistor on which an etch stop layer and a dielectric layer are deposited and a contact hole formed above a silicide region according to the first embodiment of the present invention.

FIG. 2 shows a plasma treatment of a TiN layer that is formed by a TiCl₄ based CVD or PECVD method on the dielectric layer and within the contact hole depicted in FIG. 1.

FIG. 3 is a cross-sectional view of the plasma treated structure in FIG. 2 after a metal layer is used to fill the contact hole and a planarization of the TiN layer and the metal layer is performed.

FIG. 4 is a cross-sectional view showing a plasma treatment of a TiN layer formed on a dielectric layer and within a contact hole according to a second embodiment of the present invention.

FIG. 5 is cross-sectional view of the structure in FIG. 4 after a photoresist is coated on the treated TiN layer and fills the contact hole.

FIG. 6 is a cross-sectional view of the structure in FIG. 5 after the photoresist layer and then the TiN layer is etched back to a level below the top of the contact hole.

FIG. 7 is a cross-sectional view of a completed MIM capacitor in which an insulator layer is formed on the dielectric layer and above the TiN layer depicted in FIG. 6 and a metal layer is formed on the insulator layer.

FIG. 8 is a plot showing an improved stability in resistivity when a TiN layer is treated with a plasma step according to the present invention and then exposed to an ambient.

FIG. 9 is a plot showing an improved resistance to oxidation in a TiN layer that has been treated with a plasma step according to a method of the present invention.

FIG. 10 is a plot depicting a lower leakage current in a TiN layer treated by a plasma step of the present invention.

### DETAILED DESCRIPTION OF THE INVENTION

The present invention is a method of lowering the resistivity and stress in a metal nitride layer formed by a MClₓ based CVD method where M is a metal and x is an integer. A plasma treatment is used to densify a metal nitride layer and remove impurities which improves the metal nitride film properties. The drawings are provided as examples and are not intended to limit the scope of the invention.

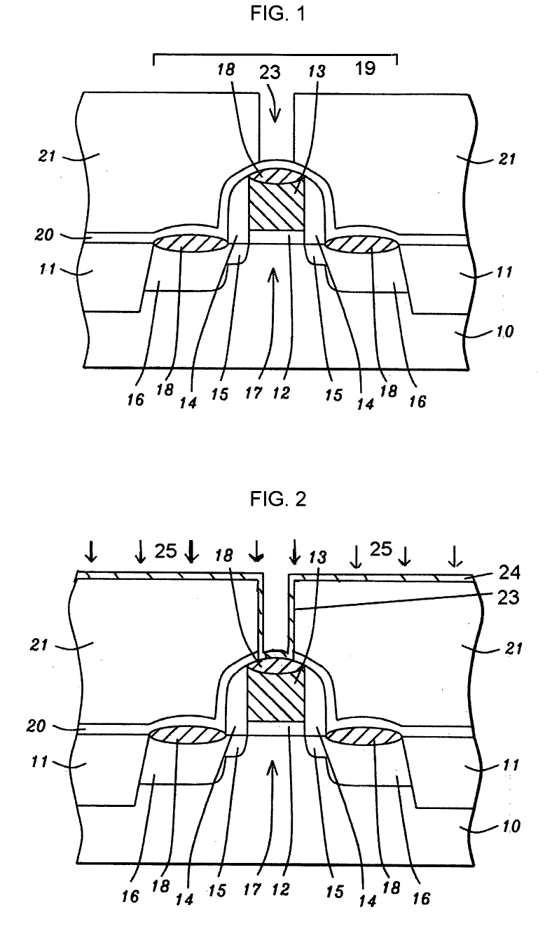

In a first embodiment shown in FIGS. 1-3, the metal nitride layer is preferably a TiN layer which is used as a barrier layer in a contact hole that is formed above a metal silicide element in a transistor. However, those skilled in the art will appreciate that the method of the first embodiment may also apply to a TiN layer formed in other applications. For example, the TiN layer may be a diffusion barrier layer deposited in an opening in a damascene process where the opening is a via, trench, or a trench formed above a via. Alternatively, the TiN layer may be deposited as an ARC layer on a metal layer prior to a photoresist patterning process. The method is particularly useful for a TiN layer that is deposited by a CVD method in which TiCl₄ is used as the titanium source gas.

Referring to FIG. 1, a transistor is illustrated on a substrate 10 and is formed on an active region 19 between isolation regions 11. The substrate 10 is typically silicon but may also be silicon-on-insulator, SiGe, SiGeC, or other semiconductor materials employed in the art. The transistor may be a Metal Oxide Semiconductor Field Effect Transistor (MOSFET) in which the substrate 10 is comprised of an n-well or a p-well. The isolation regions 11 which are formed by a conventional method are depicted as shallow trench isolation (STI) regions but may be mesa isolation regions or the like and are generally comprised of SiO₂ or a low k dielectric material. The transistor is comprised of a gate dielectric layer 12, gate electrode 13, spacers 14, extension regions 15, deep source/drain regions 16, channel region 17, and silicide regions 18 and is formed by methods known to those skilled in the art which will not be described herein. The silicide regions 18 may be comprised of one or more of Ni, Co, W, Ta, Pt, Ti, and Pd.

An etch stop layer 20 such as silicon nitride, silicon carbide, or silicon oxynitride is formed on the isolation regions 11, silicide regions 18, and spacers 14 by a CVD or plasma enhanced CVD (PECVD) method. Typically, the etch stop layer 20 forms a) conformal layer on the surface of the transistor. A dielectric layer 21 is then deposited on the etch stop layer 20 by a CVD, PECVD, or spin-on method. The dielectric layer 21 is comprised of SiO₂ or a low k dielectric material such as fluorine doped SiO₂, carbon doped SiO₂, a polysilsesquioxane, a poly(arylether), fluorinated polyimide, or benzocyclobutene. Additional processing may follow such as an anneal or plasma treatment step to densify the dielectric layer 21. Furthermore, a planarization step may be employed to form a smooth surface on the dielectric layer 21 which will improve the process latitude of a subsequent patterning step.

A contact hole 23 is formed above a suicide region 18 by a conventional sequence in which a photoresist layer (not shown) is coated and patterned on the dielectric layer 21 and the resulting photoresist pattern serves as a mask while openings in the pattern are transferred through the dielectric layer by a plasma etch. Although a contact hole 23 is shown above the gate electrode 13, other designs are possible. For example, a contact hole may be formed above each of the two suicide regions 18 on the deep source/drain regions 16.

Referring to FIG. 2, the contact hole 23 is transferred through the etch stop layer 20 by a second plasma etch step that is usually based on a fluorocarbon chemistry. At this point, the photoresist pattern is stripped by a conventional method and a standard RCA cleaning process may be used to remove any organic residues within the contact hole 23. Next, a TiN layer 24 is deposited by a CVD process. In one embodiment, the substrate 10 is loaded into a CVD process chamber and then conditions within the chamber are adjusted to a sub-atmospheric pressure and an elevated temperature that may be above 500° C. TiCl₄ and NH₃ are flowed into the chamber and react to form a TiN layer 24 on the substrate 10. The deposition step continues for a sufficient duration until an acceptable thickness of the TiN layer is reached. Preferably, the TiN layer 24 is essentially conformal to the surface of the dielectric layer 21 and sidewalls and bottom of the contact hole 23. After an acceptable thickness of TiN layer 24 is deposited, the substrate 10 is removed from the chamber. It is understood that there may be multiple chambers in the CVD process tool and that a substrate may be moved from one chamber to another chamber without exposure to air.

A key feature of the present invention is a plasma treatment step 25 which is performed in an “ex-situ” mode and preferably in a second chamber within the same CVD process tool (mainframe) as used for the previous CVD step. The substrate 10 with the transistor structure and overlying TiN layer 24 as pictured in FIG. 2 is loaded in the second process chamber and is subjected to a plasma treatment step 25. An important condition of the plasma treatment step 25 is that a nitrogen (N) containing gas is flowed into the second process chamber as a plasma is generated. Preferably, the N containing gas is N₂. However, NH₃ or N₂H₄ are also acceptable. In an alternative embodiment, N₂ is used in combination with H₂. Preferred conditions are a N containing gas flow rate of 500 to 2000 standard cubic centimeters per minute (sccm), a chamber pressure of from 1 to 10 Torr, a RF power between about 400 and 1000 Watts, and a temperature between about 500° C. and 700° C. for a period that is at least 30 seconds in length. In an exemplary mode, the plasma treatment step 25 is comprised of a N₂ flow rate of 1000 sccm, a RF power of 800 Watts, a 4.8 Torr chamber pressure, and a chamber temperature of 650° C. for a one minute duration.

It is believed that N radicals react with chloride ions that are trapped within the TiN layer 24 during the plasma treatment step 25 which forms a volatile NClx compound that is removed through an exhaust port in the process chamber. Preferably, the plasma treatment 25 is performed at a temperature of at least 500° C. in order to accelerate the chloride removal process. Those skilled in the art will appreciate that a plasma process generates reactive N radicals which are more efficient in removing chloride impurities than a prior art annealing process with a N containing gas. The plasma treatment 25 also densifies the TiN layer 24.

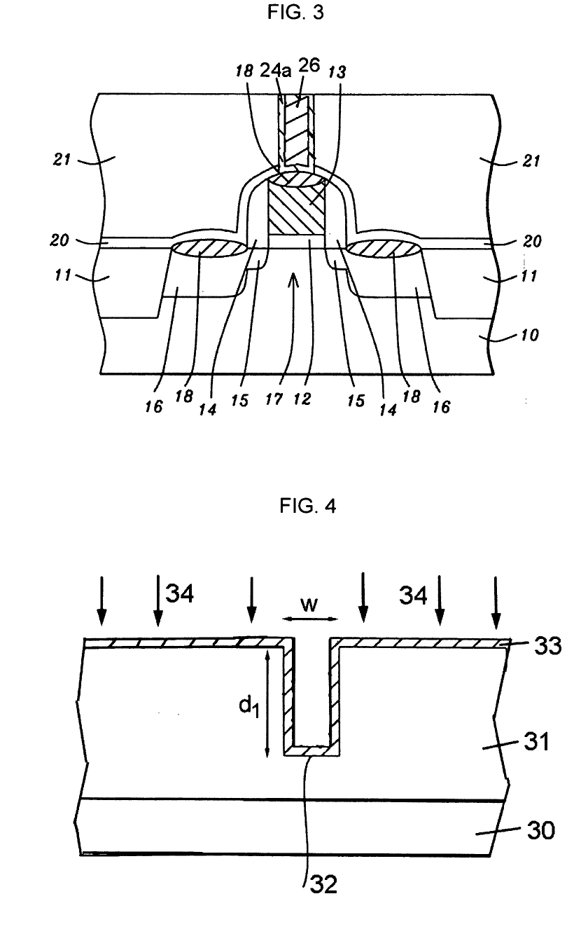

Referring to FIG. 3, the inventors have observed that the plasma treatment step 25 results in a transformed TiN layer 24a which has a lower resistivity and lower stress than the TiN layer 24. As shown in Table 1, a plasma treatment step 25 is successful in reducing resistivity and stress in a treated TiN layer 24a by 48% and 45%, respectively, compared with a TiN layer 24 that is untreated. A reduced stress is important since it prevents cracking in the transformed TiN layer 24a while a low resistivity is important for a low contact resistance. Only one step is needed to transform the TiN layer to provide improved film properties while many prior art treatment methods require two or more steps. Additional process steps are costly in terms of extra process time and equipment usage.

TABLE 1
TiN Film Properties Before and After Plasma Treatment Step 25

| | Thickness | Resistivity | Stress (×E10 |
|---|---|---|---|
| Sample | (Angstroms) | (μOhm-cm) | Dyne/cm²) |
| Layer 24 | 191 | 306 | 3.25 |
| Layer 24a | 193 | 158 | 1.79 |

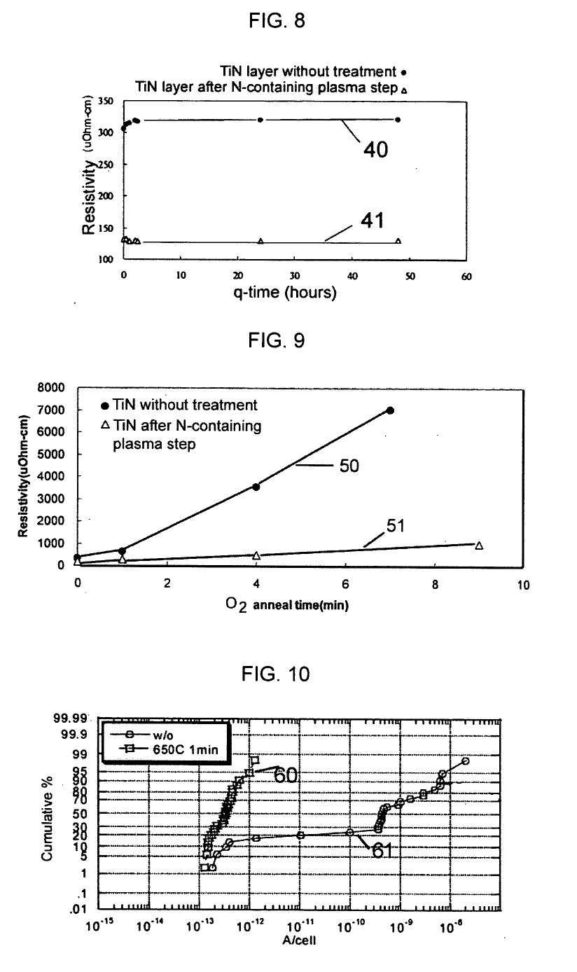

A further advantage of the plasma treatment 25 of the present invention is that it imparts improved film stability to the transformed TiN layer 24a. For example, when the samples in Table 1 were exposed to ambient (air) for a period of time (q-time) that varied between 0 and 48 hours, the resistivity for TiN layer 24 increased from 306 μOhm-cm at t=0 to 322 μOhm-cm after 48 hours which is an increase of 5.2%. During a similar period of 48 hours, the transformed TiN layer 24a had a stable 158 μOhm-cm resistivity with a 0% increase. Presumably, the resistivity increase for the untreated TiN layer 24 is due to a surface oxidation to form a titanium oxide layer. Stability as a function of q-time is graphically expressed in FIG. 8 where a TiN layer that has not been subjected to a N-containing plasma treatment experiences an increase in resistivity (curve 40) while a TiN layer treated by a method according to the first embodiment shows a stable resistivity (line 41).

Returning to FIG. 3, a conventional sequence is followed to deposit a metal layer 26 on the transformed TiN layer 24a and planarize the resulting metal layer. Typically, a metal such as copper is deposited by an electroless, electroplating, or PVD method on the transformed TiN layer 24a to a thickness that is higher than the top of the contact hole. Optionally, a seed layer may be formed on the transformed TiN layer 24a before the metal layer 26 is deposited. A planarization process such as a chemical mechanical polish (CMP) process is then employed to make the TiN layer 24a and metal layer 26 coplanar with the dielectric layer 21. Because of the lower resistivity, lower stress, and improved stability of the transformed TiN layer 24a, a higher performance and better reliability is achieved in the final device.

In a second embodiment depicted in FIGS. 4-7, the present invention is employed to form a TiN layer which serves as a bottom electrode in a MIM capacitor. Referring to FIG. 4, a substrate 30 is provided that is typically silicon but may optionally be based on Si—Ge, SiGeC, Ga—As or other semiconductor materials employed in the art. A dielectric layer 31 having a thickness from about 2000 to 20000 Angstroms is then deposited on the substrate 30 by a CVD, PECVD, or spin-on method. The dielectric layer 31 is comprised of SiO₂ or a low k dielectric material such as fluorine doped SiO₂, carbon doped SiO₂, a polysilsesquioxane, a poly(arylether), fluorinated polyimide, or benzocyclobutene. Additional processing may follow such as an anneal or plasma treatment step to densify the dielectric layer 31. Furthermore, a planarization step may be employed to form a smooth surface on the dielectric layer 31 which will improve the process latitude of a subsequent patterning step.

A contact hole 32 is formed in the dielectric layer 31 by a conventional sequence in which a photoresist layer (not shown) is coated and patterned on the dielectric layer 31 and the resulting photoresist pattern serves as a mask while openings in the pattern are transferred through the dielectric layer by a plasma etch. The pattern typically comprises other openings (not shown) besides the contact hole 32. For example, a plurality of contact holes may be formed in a design that includes isolated, semi-isolated, and dense contact hole arrays. The width w of the contact hole 32 and any other contact holes in the pattern may vary from less than 0.1 micron to over 1 micron. The contact hole 32 has a depth d₁.

A metal nitride layer 33 that is preferably comprised of TiN with a thickness of between about 100 and 500 Angstroms is deposited by a CVD process on the dielectric layer 31. In one embodiment, TiCl₄ and NH₃ are flowed into a chamber at a sub-atmospheric pressure and an elevated temperature that may be greater than 500° C. and react to form a TiN layer 33 on the dielectric layer 31. The deposition step continues for a sufficient duration until an acceptable thickness of the TiN layer is reached.

Preferably, the TiN layer 33 is essentially conformal to the surface of the dielectric layer 31 and sidewalls and bottom of the contact hole 32. After an acceptable thickness of the TiN layer 33 is deposited, the substrate 30 is removed from the chamber. It is understood that there may be multiple chambers in the CVD process tool and that a substrate may be moved from one chamber to another chamber without exposure to air.

Those skilled in the art will appreciate that the metal nitride layer 33 may optionally be TaN or WN, for example, that are deposited by a CVD process that includes a metal chloride precursor and NH₃.

A key feature of the present invention is a plasma treatment step 34 which is performed in an “ex-situ” mode and preferably in a second chamber within the same CVD process tool (mainframe) as used for the previous CVD step. The substrate 30 with the dielectric layer 31 and TiN layer 33 as pictured in FIG. 4 is loaded in the second process chamber and is subjected to a plasma treatment step 34. An important condition of the plasma treatment step 34 is that a nitrogen (N) containing gas is flowed into the second process chamber as a plasma is generated. Preferably, the N containing gas is N₂. However, NH₃ or N₂H₄ are also acceptable. In an alternative embodiment, N₂ is used in combination with H₂. Preferred conditions are a N containing gas flow rate of 500 to 2000 standard cubic centimeters per minute (sccm), a chamber pressure of from 1 to 10 Torr, a RF power between about 400 and 1000 Watts, and a temperature between about 500° C. and 700° C. for a period that is at least 30 seconds in length. In one example of a preferred mode, the plasma treatment step 34 is comprised of a N₂ flow rate of 1000 sccm, a RF power of 800 Watts, a 4.8 Torr chamber pressure, and a chamber temperature of 650° C. for a one minute duration. Note that the plasma treatment 34 is performed at a temperature of at least 500° C. in order to accelerate the removal of chloride impurities and to densify the TiN layer 33.

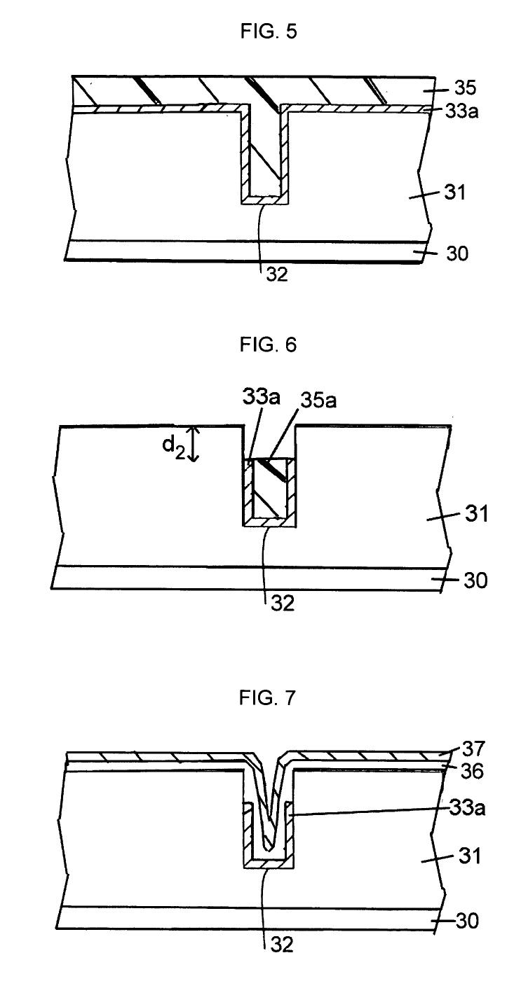

Referring to FIG. 5, the inventors have observed that the plasma treatment step 34 results in a transformed TiN layer 33a which has a lower resistivity and lower stress than the TiN layer 33. As discussed previously with respect to Table 1, a N-containing plasma treatment step 34 is successful in reducing resistivity and stress in a treated TiN layer by 48% and 45%, respectively, compared with a TiN layer that is untreated. A reduced stress is important since it prevents cracking in the transformed TiN layer 33a while a low resistivity is important for a bottom electrode in a MIM capacitor. Only one step is needed to transform the TiN layer to provide improved film properties while many prior art treatment methods require two or more steps. Additional process steps are costly in terms of extra process time and equipment usage.

A further advantage of the plasma treatment 34 of the present invention is that improved film stability is achieved in the transformed TiN layer 33a. Stability as a function of q-time is graphically expressed in FIG. 8 where a TiN layer that has not been subjected to a plasma treatment 34 experiences a 5.2% increase in resistivity (line 40) when exposed to ambient (air) while a TiN layer treated by a method according to the first embodiment shows a stable resistivity with 0% change (line 41).

The next step in fabricating a MIM capacitor is to form a bottom electrode comprised of the transformed TiN layer 33a. In one embodiment, a photoresist is coated on the transformed TiN layer 33a at a thickness that fills the contact hole 32 and forms an essentially planar photoresist layer 35.

Referring to FIG. 6, the photoresist layer 35 is removed except for a plug 35a that extends from the bottom of the contact hole 32 to a depth d₂ about 0 to 2000 Angstroms below the top of the contact hole by a plasma etch step that may include Ar and O₂, for example. A second etch step that is typically comprised of a plasma containing Cl₂ is employed to remove the exposed TiN layer 33a. The second plasma etch step preferably stops on the plug 35a and as a result, the transformed TiN layer 33a is now recessed to a depth of d₂ in the contact hole 32. It is understood that the first and second plasma etch steps also form a recessed TiN layer 33a in other contact holes in the pattern.

Referring to FIG. 7, the plug 35a is removed by a method known to those skilled in the art which may be an organic stripper solution. An insulator layer 36 is deposited on the dielectric layer 31 and on the recessed TiN layer 33a by a CVD, PECVD, or atomic layer deposition (ALD) method. In the preferred embodiment, the insulator layer 36 is a high k dielectric material such as Ta₂O₅. Optionally, one or more of TiO₂, Al₂O₃, ZrO₂, HfO₂, Y₂O₃, and La₂O₃ or a silicate, nitride, or oxynitride of Ti, Ta, Al, Zr, Hf, Y, and La may be deposited as a high k insulator layer 36. A high k dielectric material is intended to mean a dielectric material having a dielectric constant or k value of about 10 or higher. Typically, the insulator layer 36 forms a conformal layer within the contact hole 32 and on the dielectric layer 31. The insulator layer 36 is then annealed in an oxygen ambient by a conventional method.

An important requirement of the bottom electrode 33a is that it must be resistant to oxidation because the bottom electrode is exposed to oxygen during the formation of the insulator layer 36. A bottom electrode comprised of an untreated TiN layer will form titanium oxide which typically results in a high leakage current. An experiment was performed to demonstrate the improved oxidation resistance of a TiN layer 33a that has been treated by a method of the present invention. As illustrated in FIG. 9, an untreated TiN layer (curve 50) and a plasma treated TiN layer (curve 51) were subjected to rapid thermal oxidation (RTO) conditions of 450° C. and a 4.9 standard liter per minute (slm) flow rate of O₂ in a process chamber for various periods of time. The resistivity of the untreated TiN layer increased dramatically with time while the resistivity of the treated layer increased at a much slower rate. The advantage of a lower resistivity in a treated TiN layer 33a that serves as a bottom electrode in a MIM capacitor is a higher performance and improved reliability in the final device.

The MIM capacitor is completed by depositing a metal layer 37 on the insulator layer 36 by a conventional method. The metal layer 37 may be comprised of copper, for example. Note that the metal layer 37 also forms an essentially conformal layer on the insulator layer 36. Further processing may include deposition of a second dielectric layer (not shown) on the metal layer 37 and planarizing the second dielectric layer.

Another advantage of employing a plasma treated TiN layer 33a as a bottom electrode is shown in FIG. 10. Curve 60 represents leakage current in a MIM capacitor that was fabricated with a plasma treated TiN layer as a bottom electrode in which the plasma treatment included a N₂ plasma and a 650° C. chamber temperature for a period of 1 minute. Curve 61 indicates a higher leakage current for an untreated TiN bottom electrode. Thus, a lower leakage current is an additional benefit of implementing a plasma treated TiN bottom electrode in a MIM capacitor.

While this invention has been particularly shown and described with reference to, the preferred embodiment thereof, it will be understood by those skilled in the art that various changes in form and details may be made without departing from the spirit and scope of this invention.

1. A method for processing a TiN layer on a substrate, comprising:
(a) providing a substrate;
(b) depositing a TiN layer with a halogen containing titanium source gas and a nitrogen source gas on said substrate in a first process chamber; and
(c) subjecting the TiN layer to a plasma treatment involving a N-containing gas.

2. The method of claim 1 wherein said nitrogen source gas is NH₃.

3. The method of claim 1 wherein said halogen containing titanium source gas is TiCl₄.

4. The method of claim 1 wherein said deposition is a chemical vapor deposition.

5. The method of claim 1 wherein the plasma treatment is performed ex-situ in a second process chamber.

6. The method of claim 1 wherein said plasma treatment comprises a N-containing gas flow rate of 500 to 2000 sccm, a chamber temperature between about 500° C. and 700° C., a RF power from about 400 Watts to 1000 Watts, a chamber pressure of about 1 to 10 Torr, and a process time of at least 30 seconds.

7. The method of claim 6 wherein said N-containing gas is one of N₂, NH₃, or N₂H₄.

8. The method of claim 7 further comprised of adding H₂ to N₂ during the plasma treatment.

9. The method of claim 1 further comprised of depositing a metal layer on the TiN layer after the plasma treatment and planarizing to form a contact.

10. A method for processing a TiN barrier layer on a substrate, comprising:
(a) providing a substrate with an opening formed therein, said opening has sidewalls, a top, and a bottom;
(b) depositing a TiN layer with a halogen containing titanium source gas and a nitrogen source gas in a first process chamber, said TiN layer is formed by a CVD process and forms an essentially conformal layer on the substrate and on the sidewalls and bottom of said opening;
(c) subjecting the TiN layer to a plasma treatment involving a N-containing gas; and
(d) depositing a metal layer on the plasma treated TiN layer that fills the opening.

11. The method of claim 10 further comprised of performing a planarization that makes the TiN layer and metal layer coplanar with the top of the opening.

12. The method of claim 10 wherein said substrate is comprised of a top layer which is a dielectric layer.

13. The method of claim 10 wherein said halogen containing titanium source gas is TiCl₄ and said nitrogen source gas is NH₃.

14. The method of claim 10 wherein the plasma treatment is performed ex-situ in a second process chamber.

15. The method of claim 10 wherein said plasma treatment comprises a N-containing gas flow rate of 500 to 2000 sccm, a chamber temperature between about 500° C. and 700° C., a RF power from about 400 Watts to 1000 Watts, a chamber pressure of about 1 to 10 Torr, and a process time of at least 30 seconds.

16. The method of claim 15 wherein said N-containing gas is one of N₂, NH₃, or N₂H₄.

17. The method of claim 16 further comprised of adding H₂ to N₂ during the plasma treatment.

18. The method of claim 10 wherein the opening is a contact hole formed above a silicide region on a transistor.

19. A method of forming a MIM capacitor, comprising:
(a) providing a substrate with a dielectric layer formed thereon;
(b) forming a contact hole in said dielectric layer, said contact hole has sidewalls, a top, and a bottom;
(c) depositing a TiN layer with a halogen containing titanium source gas and a nitrogen source gas in a first process chamber, said TiN layer is formed by a CVD process and forms an essentially conformal layer on the dielectric layer and on the sidewalls and bottom of said contact hole;
(d) subjecting the TiN layer to a plasma treatment involving a N-containing gas;
(e) etching back the TiN layer to a recessed depth within the contact hole;
(f) depositing an insulating layer on the recessed TiN layer; and
(g) depositing a metal layer on the insulating layer.

20. The method of claim 19 wherein the dielectric layer is comprised of SiO₂ or a low k dielectric material such as fluorine doped SiO₂, carbon doped SiO₂, a polysilsesquioxane, a poly(arylether), fluorinated polyimide, or benzocyclobutene and has a thickness of about 2000 to 20000 Angstroms.

21. The method of claim 19 wherein said halogen containing titanium source gas is TiCl₄ and said nitrogen source gas is NH₃.

22. The method of claim 19 wherein the TiN layer has a thickness of about 100 to 500 Angstroms.

23. The method of claim 19 wherein the plasma treatment is performed ex-situ in a second process chamber.

24. The method of claim 19 wherein said plasma treatment comprises a N-containing gas flow rate of 500 to 2000 sccm, a chamber temperature between about 500° C. and 700° C., a RF power from about 400 Watts to 1000 Watts, a chamber pressure of about 1 to 10 Torr, and a process time of at least 30 seconds.

25. The method of claim 24 wherein said N-containing gas is one of N₂, NH₃, or N₂H₄.

26. The method of claim 25 further comprised of adding H₂ to N₂ during the plasma treatment.

27. The method of claim 19 wherein the TiN layer is recessed to a depth of about 0 to 2000 Angstroms below the top of the contact hole.

28. The method of claim 19 wherein the insulating layer is a high k dielectric layer comprised of Ta₂O₅, TiO₂, Al₂O₃, ZrO₂, HfO₂, Y₂O₃, and La₂O₃ or a silicate, nitride, or oxynitride of Ti, Ta, Al, Zr, Hf, Y, and La.

29. The method of claim 28 further comprised of annealing the insulating layer before the metal layer is deposited by a process comprising an oxygen ambient.

30. The method of claim 19 wherein the metal layer is comprised of copper.
